(19) United States
(12) Patent Application Publication
(10) Pub. No.: US 2021/0302308 A1
(43) Pub. Date: Sep. 30, 2021

(54) DIFFERENTIAL MEASUREMENT OF IR ABORPTION IN PLASMONIC MEMS SENSORS

(71) Applicant: TEXAS INSTRUMENTS INCORPORATED, Dallas, TX (US)

(72) Inventors: Jeronimo Segovia Fernandez, San Jose, CA (US); Bichoy Bahr, Richardson, TX (US); Hassan Omar Ali, Murphy, TX (US); Benjamin Stassen Cook, Los Gatos, CA (US)

(21) Appl. No.: 17/120,339

(22) Filed: Dec. 14, 2020

Related U.S. Application Data
(60) Provisional application No. 63/000,219, filed on Mar. 26, 2020.

(51) Int. Cl. G01N 21/3504; G01N 21/61; G01N 21/27; G01J 5/08; B81B 3/00

(52) U.S. Cl. CPC G01N 21/3504; G01N 21/61; B81B 2201/0292; G01J 5/0853; B81B 3/0018; G01N 21/274

(57) ABSTRACT

A differential nondispersive infrared (NDIR) sensor incorporates an infrared (IR) chopper and multiple multi-bit digital registers to store and compare parameter ratio values, as may be digitally calibrated to corresponding temperature values, from chopper clock cycle portions in which a plasmonic MEMS detector is irradiated by the IR chopper with such values from chopper clock cycle portions in which the IR detector is not irradiated by the IR chopper. The plasmonic MEMS detector is referenced to a reference MEMS device via a parameter-ratio engine. The reference device can include a broadband IR reflector or can have a lower-absorption metasurface pattern giving it a lower quality factor than the plasmonic detector. The resultant enhancements to accuracy and precision of the NDIR sensor enable it to be used as a sub-parts-per-million gas concentration sensor or gas detector having laboratory, commercial, in-home, and battlefield applications.

### CROSS-REFERENCE TO RELATED APPLICATION

This application claims priority to U.S. provisional patent application No. 63/000,219, filed 26 Mar. 2020, which is hereby incorporated by reference.

### TECHNICAL FIELD

This description relates generally to gas sensors, and more particularly to differential measurement of IR absorption using plasmonic MEMS resonators.

### BACKGROUND

A nondispersive infrared (NDIR) sensor may be useful as a spectroscopic sensor that can be used as a gas detector or otherwise to measure concentration of a gas. In some examples, NDIR sensors can use a broadband lamp source and an optical filter to select a narrowband spectral region that overlaps with the absorption region of a gas of interest. Some NDIR sensors may use microelectromechanical systems (MEMS) or mid-IR light-emitting diode (LED) sources, with or without an optical filter.

A metasurface is a thin film composed of individual nanoscale elements with features smaller than the wavelength of light, separated by subwavelength distances, and arranged to have a property not found in naturally occurring surfaces. An example plasmonic metasurface uses surface plasmons to achieve optical or opto-electronic properties not seen in nature. Plasmons are produced from the interaction of light with metal-dielectric materials. Under specific conditions, incident light couples with the surface plasmons to create self-sustaining, propagating electromagnetic waves known as surface plasmon polaritons (SPPs), which are shorter in wavelength than the incident light. Once launched, the SPPs ripple along the metal-dielectric interface.

### SUMMARY

An example NDIR sensor includes an IR chopper having an IR light source having on and off states controlled by a clock having a periodic cycle. The NDIR sensor further includes a first microelectromechanical system (MEMS) device configured as a measurement IR irradiance sensor and having a first electrical output. The NDIR sensor further includes a second MEMS device configured as a reference IR irradiance sensor and having a second electrical output. The NDIR sensor further includes a parameter ratio engine having first and second inputs to which the first and second electrical outputs are respectively coupled. The parameter ratio engine is configured to compute a ratio of one or more characteristic parameters of the first and second electrical outputs. As examples, the characteristic parameters can be amplitude, frequency, or phase. The NDIR sensor further includes digital calibration circuitry coupled to an output of the parameter-ratio engine and configured to convert the computed ratio to a multi-bit digital word representative of a temperature change induced by IR light irradiance. The NDIR sensor further includes a first multi-bit digital register coupled to the clock and to an output of the digital calibration circuitry and configured to capture a first value of the multi-bit digital word during a first time period of the clock cycle. The NDIR sensor further includes a second multi-bit digital register coupled to the clock and to an output of the first multi-bit digital register and configured to capture a second value of the multi-bit digital word during a second time period of the clock cycle. The NDIR sensor further includes a subtractor coupled to the output of the first multi-bit digital register and the output of the second multi-bit digital register and configured to subtract the second value of the multi-bit digital word from the first value of the multi-bit digital word to provide an output digital word that is proportional to an irradiance of the first MEMS device by the IR light source.

In an example method of NDIR sensing, an IR light source is periodically switched on and off with a clock period on an order of a time constant of the IR light source. For a first time period when the IR source is on, a first MEMS device, configured as a measurement IR irradiance sensor, and having a variation of the first electrical output, is irradiated with IR light from the IR light source. Also for the first time period when the IR source is on, a second MEMS device, configured as a reference IR irradiance sensor, and having a variation of the second electrical output, is irradiated with IR light from the IR light source. A first ratio of one or more characteristic parameters of the first and second electrical outputs is computed. The first ratio is digitally calibrated to a first value representative of a temperature change induced by IR light irradiance. For a second time period when the IR source is off, a second ratio of one or more characteristic parameters of the first and second electrical outputs is computed. The second ratio is digitally calibrated to a second value representative of a temperature change not induced by IR light irradiance. A difference is computed between the first value and the second value.

Another example includes an NDIR sensor that includes an IR chopper having an IR light source having on and off states controlled by a clock having a periodic cycle. The sensor further includes a first MEMS device configured as a measurement IR irradiance sensor and having a detection IR absorption response curve having a peak centered at a wavelength of interest, and the first MEMS device having a first electrical output. The sensor further includes a second MEMS device configured as a reference IR irradiance sensor and having a second electrical output. The second MEMS device is configured either as a broadband IR reflector comprising a substantially uniform metal reflecting surface, or as an IR absorber configured with a reference IR absorption response curve having a peak centered at the wavelength of interest and having a lower quality factor (“Q”) than a detection IR absorption response curve. The sensor further includes a parameter ratio engine having first and second inputs to which the first and second electrical outputs are respectively coupled, the parameter ratio engine configured to compute a ratio of one or more characteristic parameters of the first and second electrical outputs.

### BRIEF DESCRIPTION OF THE DRAWINGS

FIG. 1 is a block diagram of an example differential NDIR sensor.

FIGS. 2 and 3 are graphs showing example effects of clock frequency on the accuracy of the differential NDIR sensor of FIG. 1.

FIG. 4 is a perspective diagram of a MEMS die containing the example detector and reference devices and attached to an integrated circuit (IC) die.

FIG. 5 is a top view of example detector and reference devices of a differential NDIR sensor.

FIG. 6 is a cross-sectional view of an example reference device of a differential NDIR sensor.

FIG. 7 is a cross-sectional view of an example detector device of a differential NDIR sensor.

FIG. 8 is a top view of example detector and reference devices of a differential NDIR sensor.

FIG. 9 is a cross-sectional view of an example reference device of a differential NDIR sensor.

FIG. 10 is a cross-sectional view of an example detector device of a differential NDIR sensor.

FIGS. 11 and 12 are graphs of example absorptance profiles of detectors and references of a differential NDIR sensor.

FIG. 13 is a graph of example absorptance profiles of a detector and reference of a differential NDIR sensor.

FIG. 14 is a graph of example resonance frequency response of a detector or reference of a differential NDIR sensor.

FIG. 15 is a schematic of an example gas sensor incorporating a differential NDIR sensor.

FIG. 16 is a block diagram of an example differential NDIR sensor.

FIGS. 17 and 18 are plan-view diagrams of example detector and reference arrays as may be used in a differential NDIR sensor for gas detection or gas concentration measurement.

FIG. 19 is a flow chart of an example method for NDIR sensing.

### DETAILED DESCRIPTION

Plasmonic metasurfaces formed by a periodic set of metallic patches over grounded dielectrics with subwavelength thickness can be configured to absorb light at specific wavelengths of the infrared (IR) spectrum. A narrowband IR absorber made of one or more such plasmonic metasurfaces can be integrated with MEMS to provide sensing functionalities by converting the absorbed IR energy into an electrical output. A detector made from such an IR absorber can be designed to target a specific absorption wavelength, for example, a characteristic absorption wavelength of a gas, and therefore can be used to detect and identify gases and measure gas concentrations, among other applications.

A difficulty encountered in the employment of such sensors is that MEMS are sensitive to multiple environmental perturbations, such as temperature, device aging, humidity, and mechanical vibrations or stresses, which ultimately reduce the accuracy of the sensor. To mitigate the impact of such environmental effects on measurements, the shift in resonance frequency of a plasmonic MEMS resonator can be compared with a reference MEMS resonator, which in some examples can be a plasmonic absorber without metasurfaces. The relative IR absorption can be extracted at a specific wavelength. However, this technique of reference absorber comparison has two fundamental problems. First, it is difficult to manufacture two identical absorbers with exactly the same temperature coefficients of frequency. Fabrication tolerances introduce comparison error. Second, the difference in IR energy absorbed by devices with and without metasurfaces is relatively small and does not adequately compensate for the energy absorbed out-of-resonance. Differential NDIR sensor systems and methods as described herein improve the accuracy and resolution of plasmonic MEMS devices working as narrowband IR sensors by implementing a modulated IR light source synchronized with a digital readout system that compares one or more characteristic parameters of the electrical output of the MEMS devices and a reference MEMS device based on either a broadband reflective surface or low Q metasurfaces. In the examples described herein, the IR exposure of such a sensor is periodically changed to create an electrical output signal that can be associated to the level of irradiation energy absorbed at a specific band of detection. The impact of environmental noise can thus be reduced in essence by transmitting a specific message via IR illumination, and then on the sensor side, looking for this particular message and ignoring non-message aspects of the sensor measurement.

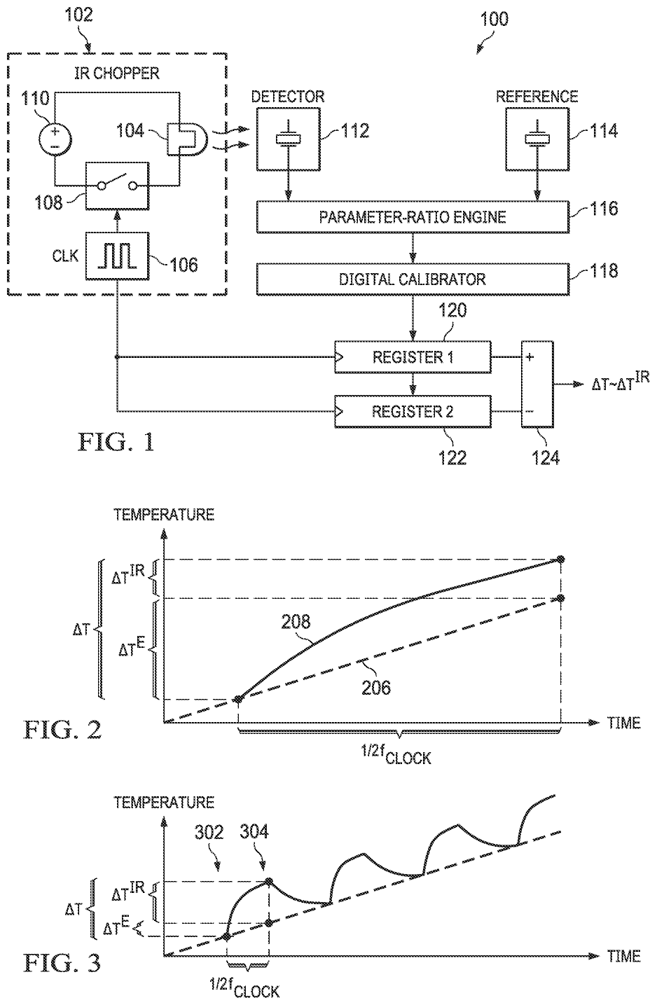

FIG. 1 illustrates an example differential NDIR sensor 100 that can be used for gas detection and characterization. Sensor 100 includes IR chopper 102 that can be used to minimize environmental effects, as may introduce noise or signal distortion into a narrowband IR detector 112, by operating IR source 104 at a clock rate f_{CLOCK} and also controlling the capture of recorded temperature data words into time-controlled registers 120, 122 at the same clock rate. The recorded temperature is a function of the IR energy absorbed by the detector 112 and can be extracted by using a parameter-ratio engine 116 configured to compare both detector 112 and reference 114 electrical outputs, and a digital calibrator 118 that in effect converts the parameter ratio into measured temperature. The parameter-ratio engine 116 can be, for example, a frequency-ratio engine configured to compare respective electrical output frequencies of detector 112 and reference 114 electrical output frequencies. In other examples, the parameter compared by parameter-ratio engine 116 can be amplitude or phase of respective output signals provided by detector 112 and reference 114.

In the example of FIG. 1, square wave generator 106 of differential NDIR sensor 100 generates a chopping clock signal CLK as a square wave of frequency f_{CLOCK} to control the opening and closing of switch 108. Switch 108 is coupled to voltage source 110 which provides electrical energy to IR source 104. IR source 104 can be any type of infrared source or blackbody radiator, which can include a lamp with a filament under vacuum that heats with application of current to emit light. In other examples, IR source 104 can be an IR photodiode, an IR MEMS source, or a photonic crystal IR emitter. The frequency f_{CLOCK} at which the chopping clock signal CLK is generated can be of such a time scale that changes in environmental temperature effects will be negligible between successive on and off states, for example, in the order of milliseconds.

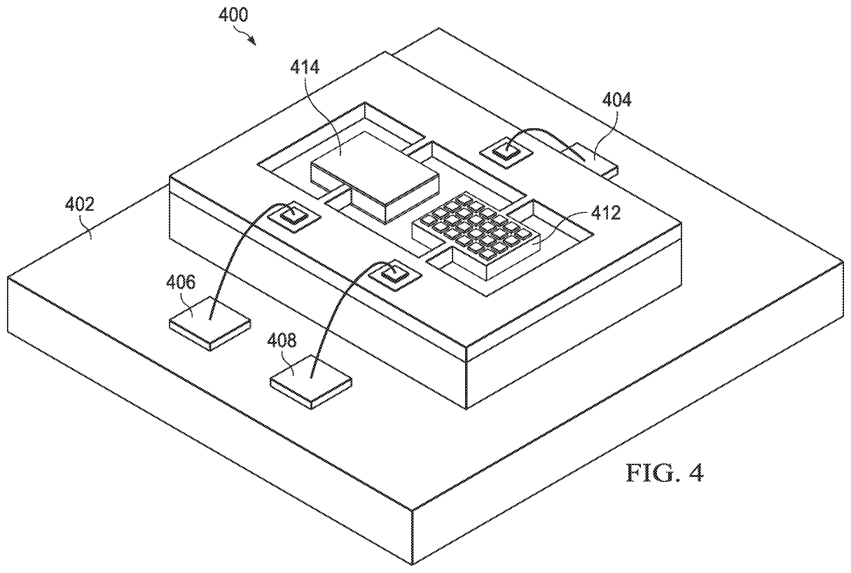

Square wave generator 106, switch 108, and voltage source 110 together function to activate IR source 104 into an ON state and deactivate IR source 104 into an OFF state. The switching between ON and OFF states of IR source 104 may not be perfectly instantaneous, but instead may have some step-function-response time constant associated with it. At the ON state, the first register 120 records the temperature measured at a time when IR source is emitting infrared energy (e.g., at time 304 in FIG. 3) while the second register 122 records the immediately previously measured OFF-state temperature from first register 120, which is a previously recorded temperature measured when the IR source 104 was most recently deactivated (e.g., at time 302 in FIG. 3). Digital subtractor 124 can determine the difference between the ON and OFF temperatures by subtracting the value stored in second register 122 from the value stored in first register 120. The resultant determined difference may then be used to determine a specific signature of interest (e.g., a gas concentration), e.g., using additional circuitry (not shown).

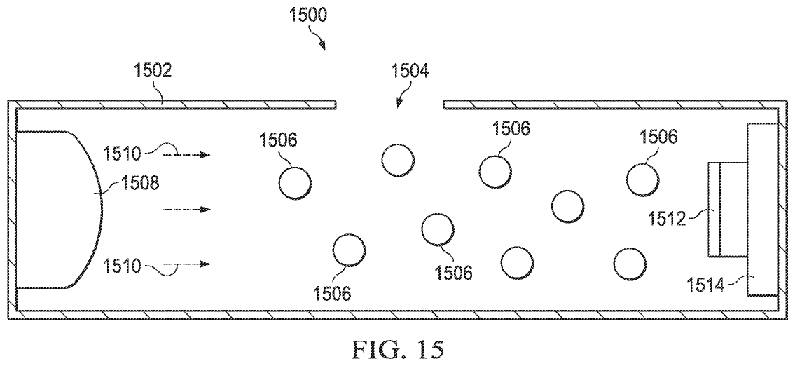

In example differential NDIR sensor 100 of FIG. 1, IR light emitted by IR source 104 passes through some medium (e.g., a gas in a sample chamber, as shown in FIG. 15) and irradiates detector 112 and reference 114. Detector 112 can be any sensor capable of measuring incident IR power at particular wavelengths, which is by providing an output electrical signal that is proportional to or in some other way corresponding to the incident IR power. In some examples, detector 112 can be any sensor capable of converting incident IR power into measurable changes in temperature. Detector 112 can be, for example, a MEMS device, which can include a metasurface, such as a plasmonic metasurface. For example, detector 112 can be a MEMS resonator. For example, the metasurface can be integrated on the MEMS device surface as a substitute for optical filters used in conventional NDIR sensors. Examples of different types of metasurfaces that can be used include periodic metallic patches, fano-resonance structures, and graphene nano-films. Detector 112 can be configured to output an electrical signal, a variation of which corresponds to temperature. Although FIG. 1 illustrates only one detector 112 and one reference 114, NDIR sensor 100 can be provided with multiple instances of detector 112 or multiple pairs of detector 112 and reference 114, each detector (or each detector/reference pair) centered at its own tailored wavelength of interest and thus targeting a specific gas signature. Detector 112 can be, for example, piezoelectrically actuated, or electrostatically actuated.

In some examples, reference 114 can be a stable oscillator, such as a quartz clock. In other examples, reference 114 can be a plasmonic MEMS device, such as a MEMS resonator, configured to absorb light beyond the wavelengths of interest. In some examples, reference 114 may be a patterned metasurface having lower quality factor (“Q”) than detector 112, or in other examples may be configured as a broadband IR reflector that can have near-zero IR absorption. In some examples, reference 114 is fabricated using the same process as detector 112, only using a different layout of the metasurface mask. For example, detector 112 can have a first plasmonic metasurface fabricated with a first pattern of metapatches, and reference 114 can have a second plasmonic metasurface fabricated with a second pattern of metapatches, with the detector 112 and the reference 114 being otherwise structurally identical in terms of the number of layers, layer materials, and layer thicknesses used to fabricate each of them.

Each of detector 112 and reference 114 transduce incident IR light to an electrical signal that is fed into parameter-ratio engine 116, which is configured to compute a ratio of one or more characteristic parameters of the two respective input electrical signals provided from detector 112 and reference 114. In some examples, the parameter-ratio engine 116 can be a frequency-ratio engine with two frequency counters configured to compare the frequencies of the output signals from detector 112 and reference 114. In other examples, parameter-ratio engine 116 can be a frequency-ratio engine that includes two nested phase-locked loops (PLLs), one an analog PLL, one a digital PLL, in which the digital PLL controls the analog PLL to derive a division ratio. In still other examples, the parameter ratio engine 116 can be an amplitude-ratio engine having a differential amplifier configured to compare the amplitudes of current or voltage of the respective output signals from detector 112 and reference 114. In still other examples, the parameter-ratio engine 116 can be a phase-ratio engine having a phase detector configured to compare the phases of the respective output signals from detector 112 and reference 114. The parameter-ratio engine can be configured to measure down to parts-per-million (PPM) or parts-per-billion (PPB) resolution.

The relation of difference in MEMS device output signal versus difference in MEMS device temperature may not be linear. Accordingly, digital calibration may be provided in example differential NDIR sensor 100 of FIG. 1 to convert from the one or more characteristic parameters of the output signal (the output of parameter-ratio engine 116) to a value that is meaningful as a temperature. As an example, digital calibrator 118 can be a digital logic device with a static function configured to translate the output of parameter-ratio engine 116 into a corresponding temperature represented as a multi-bit digital word. As one example, digital calibrator 118 can implement a polynomial transfer function. Such a polynomial can, for example, be of linear, quadratic, cubic, or greater degree.

In example differential NDIR sensor 100 of FIG. 1, clock signal CLK is also fed to respective capture inputs of each of two multi-bit digital registers 120, 122, which can each comprise, for example, a set of flip-flops configured to save time-offset outputs of digital calibrator 118 for comparison with each other. The precision of the temperature readout is determined at least in part by the bit length of the registers 120, 122. In some examples, registers 120, 122 are sixteen-bit registers. In other examples, registers 120, 122 are twenty-four-bit registers, providing sub-parts-per-million (sub-PPM) precision when the NDIR sensor 100 is used as a gas detector. Twice each clock cycle of clock signal CLK, the output of digital calibrator 118 is captured to first register 120 so in a first half of a clock cycle, first register 120 captures a measurement made when the IR source 104 is on, and in a second half of the clock cycle, first register 120 captures a measurement made in the IR source 104 is off. One half-cycle of clock signal CLK after a value is captured to first register 120, that value is shifted to second register 122 so a comparison between the two registers 120, 122 may be performed by digital subtractor 124. Digital subtractor 124 is configured to compare temperature difference measurements made in a time period with the IR source 104 ON to temperature difference measurements made in a time period with the IR source 104 OFF. These temperature difference measurements, output as a digital word, are proportional to the difference in IR irradiation absorbed between the IR detector 112 and the IR reference 114, which in turn, in a gas concentration measurement application, is equivalent to the IR irradiation emitted by the IR source minus the IR irradiation absorbed by the measured gas. The more IR light is absorbed by the gas, the less IR light is incident upon and absorbed by the detector 112 as a temperature shift and hence as a variation of the MEMS electrical output signal.

The temperature difference ΔT output by digital subtractor 124 and thus by differential NDIR sensor 100 depends not only on temperature variance due to IR power from IR source 104, but also includes the effects on MEMS output signal due to environmental perturbations, such as temperature, humidity, mechanical vibrations, and stresses. Sensor accuracy is improved by minimizing the contributions of environmental effects to ΔT, so that ΔT becomes closer to the difference in MEMS device output signal owing to the IR irradiation ΔT^{IR}.

The temperature-versus-time graphs of FIGS. 2 and 3 illustrate the effect of changes in clock rate f_{CLOCK} of clock signal CLK on the accuracy of NDIR sensor 100. The solid-line plot in each of FIGS. 2 and 3 corresponds to variation in MEMS device temperature caused by irradiation from the IR chopper 102. Assuming environmental effects, signified by the broken-line plot in each of FIGS. 2 and 3, the output difference in temperature measurement ΔT is equal to the sum of (a) the difference in temperature owing to the IR irradiation ΔT^{IR} and (b) the difference in temperature owing to environmental perturbations ΔT^{E}. Because the chopper contribution ΔT^{IR} is the component pertaining to the valuable information of interest and the environmental contribution ΔT^{E} can be considered the measurement error or noise component, ideally, environmental component ΔT^{E} should be minimized and chopper component ΔT^{IR} should be made to dominate NDIR sensor output ΔT. As shown in FIG. 2, as clock rate f_{CLOCK} decreases, NDIR sensor output ΔT becomes dominated by environmental component ΔT^{E}, corresponding to an increase in measurement error. By contrast, as shown in FIG. 3, with a sufficiently high clock rate f_{CLOCK}, for example, with ½f_{CLOCK} set to be on order of the time constant of IR source 104, e.g., on the order of milliseconds, the contribution of the environmental component ΔT^{E} to the output ΔT is reduced, and the output ΔT becomes dominated by the contribution from the IR chopper ΔT^{IR}, improving accuracy of differential NDIR sensor 100.

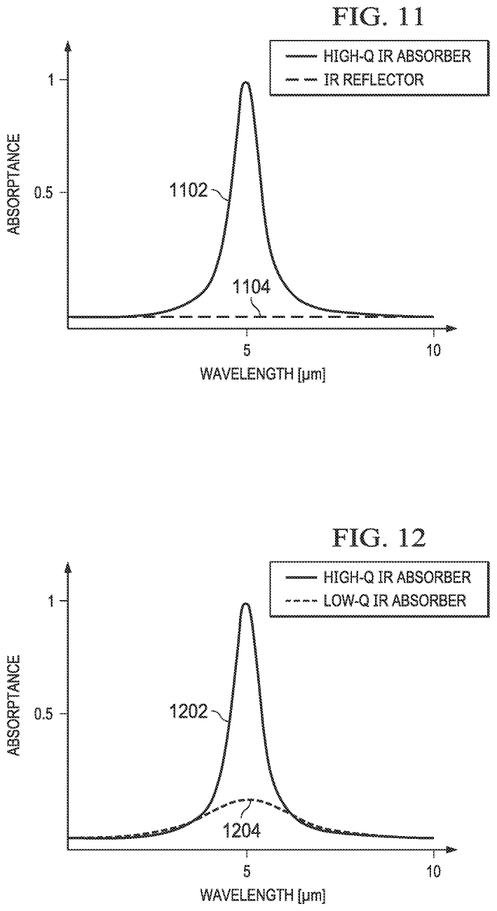

Reference 114 can be included to compensate for out-of-resonance absorption, which is to “clean out” for those wavelengths below and above a center wavelength of interest for which detector 112 is designed and patterned, and ultimately to make NDIR sensor 100 more selective to specific wavelengths. Although ideally a plasmonic MEMS device used in detector 112 absorbs light only at the wavelength of interest for which detector 112 has been designed and patterned, in practice, its absorption at other wavelengths may reduce the signal-to-noise ratio (SNR) of NDIR sensor 100. The SNR can be improved by referring the sensor response to a baseline that can compensate for the undesired out-of-band absorption. Thus, to improve resolution of differential NDIR sensor 100 of FIG. 1, in some examples, reference 114 can be, as examples, a broadband IR reflector or a low-Q plasmonic absorber centered at the same wavelength wo as detector 112. The absorptance-versus-wavelength graphs of FIGS. 11 and 12 illustrate the relative absorptance profiles of an IR reflector used as a reference versus a low-Q IR absorber used as a reference.

The perspective diagram of FIG. 4 illustrates an example MEMS die 400 attached on an integrated circuit (IC) die 402. The MEMS die can include both a high-Q IR absorber, e.g., a plasmonic metasurface, as a detector 412, which can correspond to detector 112 of FIG. 1, and a reference 414, e.g., a broadband IR reflector or a low-Q IR absorber, which can correspond to reference 114 of FIG. 1. In another example, the MEMS die can include multiple instances of a high-Q IR absorber as the detector 412, or multiple pairs of detector 412 and reference 414, individual instances of the reference being implemented, for example, as a broadband IR reflector or low-Q IR absorber. “High-Q” and “low-Q” as those terms are used herein are relative to each other. In one example, detector 412 and reference 414 are directly connected to one or two oscillator circuits that exhibit two oscillation frequencies when the MEMS devices work as mechanical resonators. In another example, detector 412 and reference 414 are interrogated by a voltage-control oscillator (VCO) that locks the MEMS resonators at frequencies close to mechanical resonance. In another example, detector 412 and reference 414 are directly connected to one or two transimpedance amplifiers that provide two output voltages when the MEMS devices are subjected to thermal expansion. Respective electrical connections 404, 406, 408 can link detector 412 and reference 414 with circuitry fabricated in the IC die 402. Such circuitry can include, for example, circuitry implementing parameter-ratio engine 116, digital calibrator 118, registers 120, 122, digital subtractor 124, and other associated electronic circuitry. MEMS and IC substrates can be, for example, silicon.

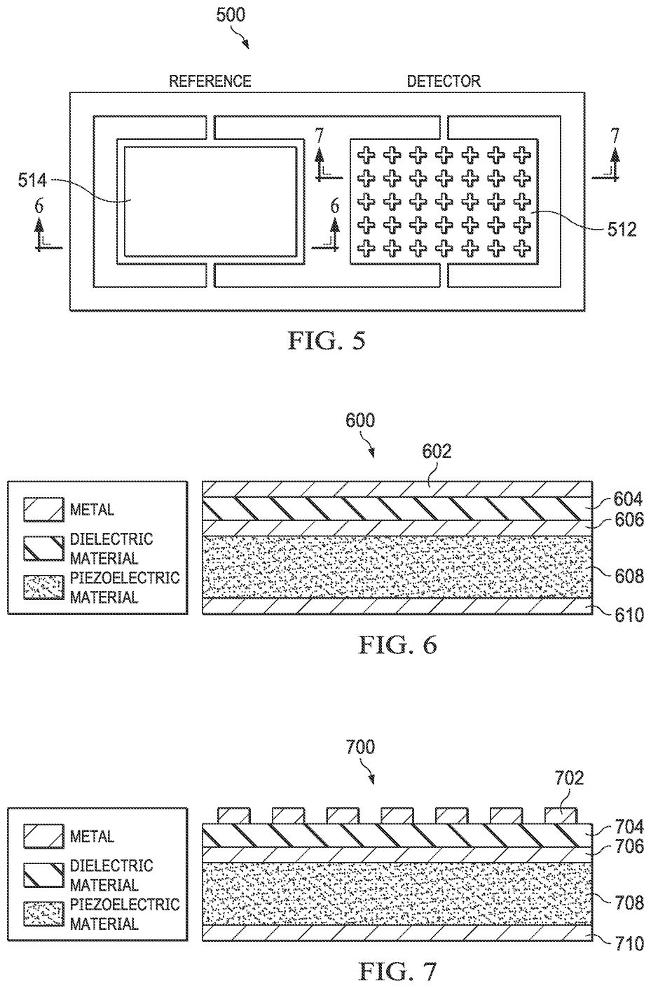

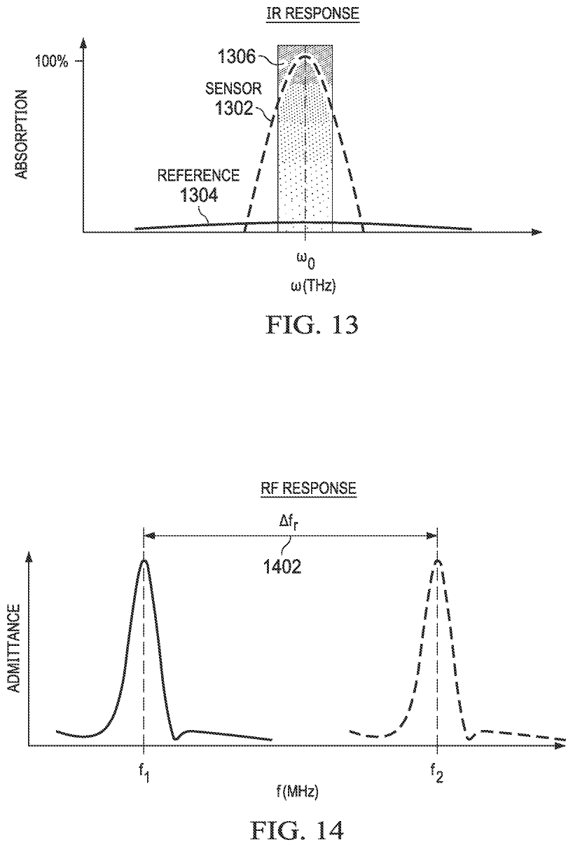

FIG. 5 shows a top (plan) view of an example MEMS device 500 that includes a high-Q IR absorber detector 512 having a patterned metasurface and a fully-plated IR reflector reference 514. In the illustrated example, the patterned metasurface is illustrated as an array of metapatches that are equivalent in shape and dimension, particularly, a regular pattern of metal crosses, but the pattern can use other shapes, such as square patches, or metapatches of multiple different shapes, and the shapes can be regular or irregular, in either size or in spacing with respect to each other. The pattern can be designed to have a particular IR absorption resonance. Line 6 indicates a cross-section of reference 514 shown as cross-section 600 in FIG. 6. Line 7 indicates a cross-section of detector 512 shown as cross-section 700 in FIG. 7. High-Q IR absorber detector 512 is, for example, a plasmonic metasurface. As shown in FIGS. 6 and 7, both detector 512 and reference 514 can be fabricated with a number of deposited layers of metal 602, 606, 610, 702, 706, 710, dielectric material 604, 704, and piezoelectric material 608, 708. As examples, the metal layers can variously be gold, platinum, aluminum, copper, or molybdenum. The dielectric material can be silicon dioxide, silicon nitride, aluminum oxide, or aluminum nitride. The piezoelectric material can be aluminum nitride, lithium niobate, gallium nitride, or PZT, with or without dopants. Top metal layer 602 of reference 514 can be, for example, of substantially uniform thickness across the entirety of the surface of reference 514 to form an IR reflector having a relatively flat IR response absorption profile (see 1104 in FIG. 11). By contrast, top metal layer 702 of detector 512 can be formed, e.g., by etching, into patterned geometrical surface features configured to tune detector 512 to a particular IR response frequency (see 1102 in FIG. 11, 1202 in FIG. 12, or 1302 in FIG. 13) that can correspond, for example, to a peak frequency in an absorption frequency profile of a gas desired to be sensed.

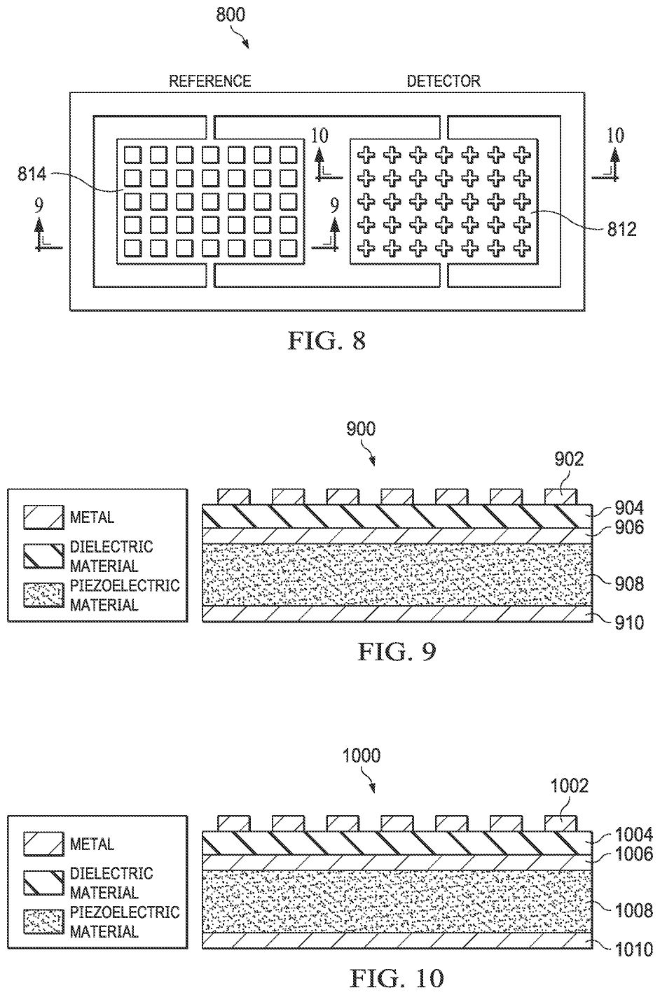

FIG. 8 shows a plan view of an example MEMS device 800 that includes a high-Q IR absorber detector 812 and a low-Q IR absorber reference 814. Line 9 indicates a cross-section of reference 814 shown as cross-section 900 in FIG. 9. Line 10 indicates a cross-section of detector 812 shown as cross-section 1000 in FIG. 10. As shown in FIGS. 9 and 10, both detector 812 and reference 814 can be fabricated with a number of deposited layers of metal 902, 906, 910, 1002, 1006, 1010, dielectric material 904, 1004, and piezoelectric material 908, 1008. High-Q IR absorber detector 812 and low-Q IR absorber reference 814 can respectively comprise, for example, plasmonic metasurfaces of different configuration. Top metal layer 1002 of detector 812 can be formed, e.g., by etching, into patterned geometrical surface features configured to tune detector 812 to a particular IR response frequency that can correspond, for example, to a peak frequency in an absorption frequency profile of a gas desired to be sensed. By contrast to substantially uniform top metal layer 602 of IR reflector reference 514, however, top metal layer 902 of reference 814 can also be formed into patterned geometrical surface features resulting in an identical or similar IR response frequency as that of detector 812, but with lower Q. As an example, high-Q detector 812 can be patterned with cross-shaped metapatches and low-Q reference 814 can be patterned with square or rectangular metapatches. The utility of such a configuration as shown in FIGS. 8-10 is explained in FIG. 12 by comparison with FIG. 11.

FIG. 11 shows an example first absorptance profile 1102 of a high-Q IR absorber, such as a plasmonic metasurface, centered at five micrometers and an example second absorptance profile 1104 of an IR reflector, which can correspond to the arrangement of FIGS. 5-7. Comparatively, the amount of IR energy absorbed below about two micrometers and above about eight micrometers is almost equivalent for both the high-Q IR absorber and the IR reflector. Consequently, the amount of IR energy absorbed beyond these wavelength limits can be neglected by computing the ratio of their respective output signals, e.g., by parameter-ratio engine 116 in FIG. 1.

FIG. 12 shows an example first absorptance profile 1202 of a high-Q IR absorber, such as a plasmonic metasurface, centered at five micrometers and an example second absorptance profile 1204 of a low-Q IR absorber, which can correspond to the arrangement of FIGS. 8-10. The absorptance profile 1204 of the low-Q IR absorber better mimics the absorptance profile 1202 of the high-Q IR absorber over a greater portion of the wavelength range than does the absorptance profile 1104 of the IR reflector, but has a lower absorption peak than profile 1202. Thus, for example, the amount of IR energy absorbed below about four micrometers and above about six micrometers is almost equivalent for both the high-Q IR absorber and the low-Q IR absorber. Consequently, the amount of IR energy absorbed beyond these comparatively less restricted wavelength limits can be neglected by computing the ratio of their respective output signals, e.g., by parameter-ratio engine 116 in FIG. 1. Use of a low-Q IR absorber rather than a broadband reflector as the reference provides the advantage of a better reference for wavelengths that are closer to the center wavelength wo. FIGS. 11 and 12 thus demonstrate the desirability in some examples of using a low-Q IR absorber as reference 114, as in the example of FIGS. 8-10, rather than a simple IR reflector, as in the example of FIGS. 5-7.

MEMS devices configured in ways other than as illustrated in FIGS. 4-10 can be used as detector 112 and reference 114 in sensor 100 of FIG. 1. As an example, a MEMS device may be patterned with metal (e.g., gold) on a piezoelectric substrate (e.g., aluminum nitride) having a metal undersurface (e.g., platinum). The metal surface can function as both metasurface and top electrode and the metal undersurface can function as a base electrode. In contrast to the resonators of FIGS. 5-10, which have separate dielectric and piezoelectric layers, a MEMS device may be configured to use the piezoelectric layer as the dielectric for the metasurface absorption. In some examples, a reference device can have a piezoelectric substrate with a metal undersurface as a base electrode, but not have a patterned metal surface or otherwise, and instead use its piezoelectric substrate as the IR-absorptive surface.

FIGS. 13 and 14 illustrate the working principle of a MEMS-resonator-based, reference-compared IR detector. FIG. 13 shows that IR light incident on a MEMS resonator is absorbed at a specific wavelength wo based on the MEMS resonator design. A detector resonator can be tailored to the wavelength wo and accordingly has an IR response 1302 having a peak centered at wo. For example, a detector resonator can be configured with an infrared absorption response curve 1302 having a peak centered within the absorption bandwidth of a gas intended to be detected. In some examples, a reference resonator may also be tailored to the wavelength wo, but with lower Q, and accordingly can have an IR response 1304 having a comparatively lower-amplitude peak also centered at wo. In other examples, such as where an IR reflector is used as the reference resonator, the reference resonator can have no particular peak (see, e.g., plot 1104 in FIG. 11). The box 1306 indicates that the amount of IR absorption is proportional to the temperature variance, which is in turn proportional to the variation in frequency. The amount of IR absorption, which, in the context of a gas detector implementation of an NDIR sensor, depends on the concentration of the gas between IR source and plasmonic metasurface sensor, is proportional to a frequency shift exhibited by the MEMS resonator, as illustrated in FIG. 14. In this way, the mid-IR frequencies (in the terahertz range) of incident light energy absorption are effectively translated to the megahertz-range resonant frequency variations that the MEMS resonator operates on. The amount of such resonant frequency variation 1402 is proportional to the amount of IR absorption, which, in the context of gas detection, is proportional to the amount of gas concentration in the chamber.

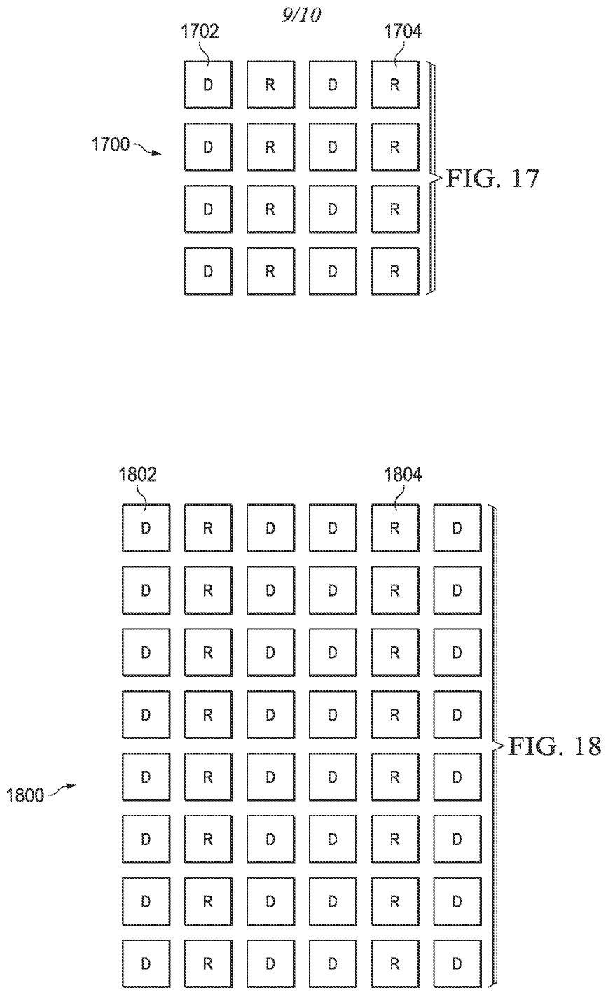

The schematic diagram of FIG. 15 illustrates a gas sensor 1500 that includes an NDIR sensor comprising MEMS die 1512 coupled to an IC (e.g., having CMOS substrate) 1514 implemented in a sample chamber 1502. The chamber can be, for example, a straight tube with reflective sidewalls, or a spiral chamber with ellipsoid reflectors. The reflective sidewalls can be coated with gold, for example, to provide the desired sidewall reflection. The chamber 1502 includes at least one opening 1504 permitting the admission of samples of gas. IR light 1510 from IR source 1508, e.g., a lamp or a photodiode, is either absorbed at one or more characteristic frequencies by gas molecules 1506 or irradiates the NDIR sensor located at an opposite end of the chamber 1502 from the IR source 1508. The level of IR absorption within the space between the IR source 1508 and the MEMS die 1512, and therefore the amount of IR irradiation at the MEMS die 1512, depends on the concentration of molecules of the target gas, because the IR power with which the MEMS die 1512 is irradiated is the remaining IR power of light 1510 after absorption by the gas 1506. The NDIR sensor can be configured as shown in FIG. 4 and the NDIR sensor and IR source 1508 can together be configured as shown in FIG. 1. MEMS die 1512 can include one or more detector and/or reference plasmonic metasurfaces, as described above. For example, MEMS die 1512 can include an array of such metasurface-based detectors to provide detection at wavelengths. Example arrays are illustrated in FIGS. 17 and 18. Gas sensor 1500, implemented as a gas detector, can further include thresholding circuitry (not shown), which in some examples be implemented on CMOS substrate 1514. The thresholding circuitry can be configured to compare the output digital word representative of the detected temperature shift ΔT to a hard-coded or programmable threshold value, and based on the detected temperature shift ΔT exceeding the threshold value, can provide a binary signal representative of positive detection of a gas of interest.

Gas sensor 1500 can be implemented in a variety of applications. For example, sensor 1500 can be provided in laboratory equipment or consumer or commercial appliances used to test biological samples, to provide detection of dangerous or unwanted gases, or to measure concentrations of gases. Such a sensor 1500 can be provided in a control loop along with a gas source and a valve to control release of a gas from the gas source so that a desired or optimum concentration of gas is controllably delivered. Gas sensor 1500 can be implemented in a mobile device, such as a mobile phone, a tablet or laptop computer, or an aerial vehicle, such as a drone, to test air quality or to check for hazardous gas or pollutant gas. Sensor 1500 can be used on a battlefield to monitor for a gas attack. A swarm of drones each provided with sensor 1500 can determine and report the coordinates of a geographic periphery of a dangerous gas cloud. Sensor 1500 can be provided in a smoke detector or a carbon monoxide detector used in the household or in the workplace. Sensor 1500 can be used in quality control contexts to monitor for gases known to be associated with rotting food or other deteriorating organic materials. Sensor 1500 can be used in environmental controls for factories or clean room environments. Sensor 1500 can be used in any application where determination of or control of presence or absence of particular gases is desired. In each of these applications, or in others that would be apparent to those skilled in the art, sensor 1500 can be used to provide a compact, high-accuracy, high-resolution (e.g., sub-PPM) gas sensor or detector.

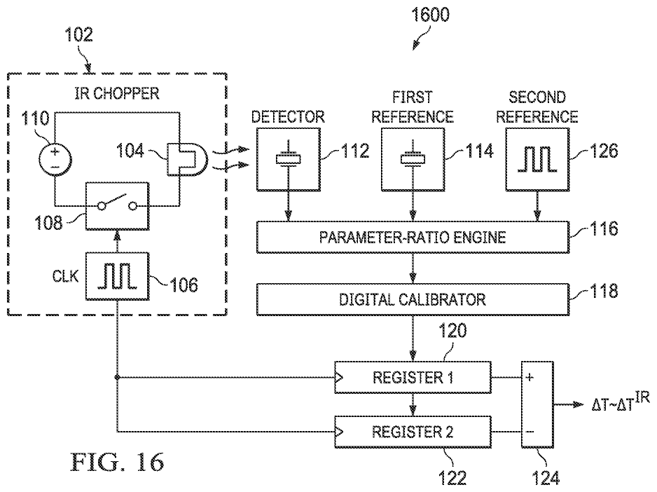

FIG. 16 illustrates an example NDIR sensor 1600 identical to sensor 100 of FIG. 1 but with the addition of a second reference 126 which can be configured as a temperature-invariant reference such as a quartz-based clock. When detector 112 and first reference 114 are configured as plasmonic metasurfaces, their electrical output signals may vary with temperature and mechanical stress and other environmental perturbations. Parameter-ratio engine 116 can thus be configured to not only compare the outputs of detector 112 and first reference 114 but also to compare these to second reference 126, which can be an external clock, to determine or account for the drift of the individual MEMS absorbers 112, 114. For example, second reference 126 can be configured to be highly stable across the range of expected temperatures. In some examples, second reference 126 is a quartz-based clock.

A given plasmonic metasurface pattern can be tailored for detecting certain wavelengths only. A detector (e.g., detector 112) connected to a specific input of the parameter-ratio engine 116 may be patterned with metapatches to configure the detector with a particular wavelength of interest, e.g., to detect a particular gas. Accordingly, an NDIR sensor (e.g., NDIR sensor 100) can be fabricated with one or more MEMS-based detectors 112 customized to the intended application, e.g., to one or more particular gases intended to be sensed. In some examples, an NDIR sensor can be provided with multiple metasurface-based detectors tailored to detect different wavelengths. The provision of such multiple metasurface-based detectors can be used either to provide detection capability of multiple different wavelengths of interest, e.g., to identify multiple different gases, and/or to provide confidence in the identification of a single gas. For example, if it is known that a particular gas has four different characteristic absorption peaks, an NDIR sensor (e.g., NDIR sensor 100) can be provided with four different metasurface-based detectors (e.g., four different instances of detector 112), each aligned to one of the wavelengths of the four different characteristic absorption peaks of the gas of interest. Greater certainty or confirmation of detection of the gas of interest is provided based on multiple or all of the plasmonic metasurface sensors indicating detection (“triggering”), in some examples by comparison to one or more threshold values.

FIGS. 17 and 18 illustrate example arrays 1700, 1800 of different metasurfaces that can be used for NDIR detection, e.g., in gas detection applications. In the example of FIG. 17, array 1700 has eight different metasurface-based detectors 1702 (labeled “D”) individually referenced to eight respective references 1704 (labeled “R”) to provide, for example, detection of multiple gases or confidence in the identification of one or more gases. Other array configurations are possible, e.g., arrays having two-by-two detectors/references or eight-by-eight detectors/references. In some examples, such as that of FIG. 17, each metasurface-based detector can be paired with its own reference. Such a configuration may be necessary where high-Q detector and low-Q reference are focused on the same wavelength. Where an IR reflector is used as the reference, however, it can be used as a reference common to multiple detectors of potentially varying metasurface designs so one or more detectors can be referenced to a single reference. Such an example is shown in FIG. 18, wherein an array 1800 has thirty-two detectors 1802 and sixteen references 1804 so each reference is paired to two detectors. So that a detector and a corresponding reference to which the detector is paired experience as close as possible to the same temperature and stress on the chip on which they are fabricated during operation, the detector and the reference can be located spatially as close as possible to each other. If a detector and its respective reference are located too far apart from each other, within-chip temperature gradients or stress gradients may result in the reference and the detector no longer seeing the same environment.

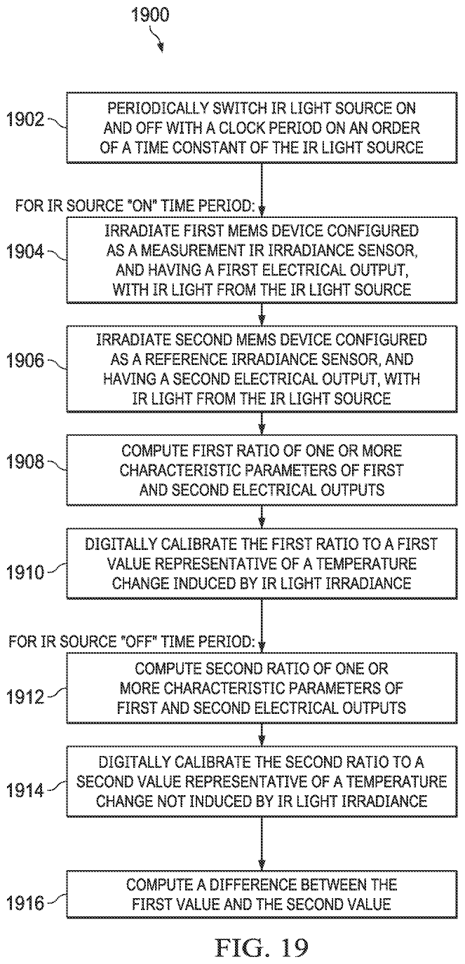

FIG. 19 illustrates an example method 1900 of NDIR sensing. An IR light source (e.g., IR source 104 in FIG. 1) is periodically switched on and off 1902 with a clock period on an order of a time constant of the IR light source. For a first time period when the IR source is on, a first MEMS device (e.g., detector 112, 412, 512, or 812), configured as a measurement IR irradiance sensor, and having a first electrical output, is irradiated 1904 with IR light from the IR light source. Also for the first time period when the IR source is on, a second MEMS device (e.g., reference 114, 414, 514, or 814), configured as a reference IR irradiance sensor, and having a second electrical output, is irradiated 1906 with the IR light from the IR light source. A first ratio of one or more characteristic parameters of the first and second electrical outputs is computed 1908 (e.g., by parameter-ratio engine 116). The first ratio is digitally calibrated 1910 (e.g., by digital calibrator 118) to a first value representative of a temperature change induced by IR light irradiance. For a second time period when the IR source is off, a second ratio of one or more characteristic parameters of the first and second electrical outputs is computed 1912 (e.g., by parameter-ratio engine 116). The second ratio is digitally calibrated 1914 (e.g., by digital calibrator 118) to a second value representative of a temperature change not induced by IR light irradiance. A difference is computed 1916 (e.g., by digital subtractor 124) between the first value (e.g., stored in first register 120) and the second value (e.g., stored in second register 122). This difference may then be indicative of absorption at the wavelength(s) of interest and thus of the presence, absence, or concentration of a gas of interest in gas detection or gas measurement applications.

The NDIR sensors and methods described herein reduce the impact of environmental perturbations on NDIR sensor resonance frequency measurements, thereby improving accuracy, as well as lowering the out-of-band energy absorption, thereby improving resolution. These features enable the use plasmonic MEMS devices in applications such as gas monitoring.

In this description, the term “based on” means based at least in part on. Also, in this description, the term “couple” or “couples” means either an indirect or direct wired or wireless connection. Thus, if a first device, element, or component couples to a second device, element, or component, that coupling may be through a direct coupling or through an indirect coupling via other devices, elements, or components and connections. Similarly, a device, element, or component that is coupled between a first component or location and a second component or location may be through a direct connection or through an indirect connection via other devices, elements, or components and/or couplings. A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device that is described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or IC package) and may be configured to couple to at least some of the passive elements and/or the sources to form the described structure either at a time of manufacture or after a time of manufacture, such as by an end-user and/or a third-party.

Modifications are possible in the described embodiments, and other embodiments are possible, within the scope of the claims.

What is claimed is:

1. A nondispersive infrared (NDIR) sensor comprising:
a clock having a periodic cycle;
an infrared (IR) chopper comprising an IR light source having on and off states controlled by the clock;
a first microelectromechanical system (MEMS) device configured as a measurement IR irradiance sensor and having a first electrical output;
a second MEMS device configured as a reference IR irradiance sensor and having a second electrical output;
a parameter-ratio engine having first and second inputs to which the first and second electrical outputs are respectively coupled, the parameter-ratio engine configured to compute a ratio of one or more characteristic parameters of the first and second electrical outputs;
digital calibration circuitry coupled to an output of the parameter-ratio engine and configured to convert the computed ratio to a multi-bit digital word representative of a temperature change induced by IR light irradiance;
a first multi-bit digital register coupled to the clock and to an output of the digital calibration circuitry and configured to capture a first value of the multi-bit digital word during a first time period of the clock cycle;
a second multi-bit digital register coupled to the clock and to an output of the first multi-bit digital register and configured to capture a second value of the multi-bit digital word during a second time period of the clock cycle; and
a subtractor coupled to the output of the first multi-bit digital register and the output of the second multi-bit digital register and configured to subtract the second value of the multi-bit digital word from the first value of the multi-bit digital word to provide an output digital word that is proportional to an irradiance of the first MEMS device by the IR light source.

2. The sensor of claim 1, wherein the one or more characteristic parameters of the first and second electrical outputs are one or more of amplitude, frequency, or phase of the first and second electrical outputs.

3. The sensor of claim 1, wherein the second MEMS device is a broadband IR reflector.

4. The sensor of claim 1, wherein the first MEMS device comprises a first plasmonic metasurface and is configured with a first IR absorption response curve having a peak centered at a wavelength of interest, and wherein the second MEMS device comprises a second plasmonic metasurface and is configured with a second IR absorption response curve having a peak centered at the wavelength of interest and having a lower quality factor than the first IR absorption response curve.

5. The sensor of claim 4, wherein the first plasmonic metasurface comprises cross-shaped metapatches.

6. The sensor of claim 5, wherein the second plasmonic metasurface comprises rectangular-shaped or square-shaped metapatches.

7. The sensor of claim 1, comprising an array of MEMS devices, in which the array includes the first and second MEMS devices and other measurement IR irradiance sensors.

8. The sensor of claim 7, wherein the array includes other reference IR irradiance sensors, and a number of the other reference IR irradiance sensors is less than a number of the other measurement IR irradiance sensors.

9. The sensor of claim 1, wherein the parameter-ratio engine is further coupled to an output of a stable clock reference and is configured to compare the first and second electrical outputs to the output of the stable clock reference.

10. A gas concentration sensor or gas detector comprising the sensor of claim 1 and a sample chamber, the IR light source arranged at an opposite end of the sample chamber from the first and second MEMS devices.

11. The gas concentration sensor or gas detector of claim 10, wherein the sample chamber comprises a straight tube with reflective sidewalls.

12. The gas concentration sensor or gas detector of claim 10, wherein the sample chamber comprises a spiral chamber with ellipsoid reflectors.

13. A nondispersive infrared (NDIR) sensing method comprising:
periodically switching an infrared (IR) light source on and off with a clock period on an order of a time constant of the IR light source;
for a first time period when the IR source is on:
irradiating a first microelectromechanical systems (MEMS) device configured as a measurement IR irradiance sensor, and having a variation of one or more characteristic parameters of the first electrical output with IR light from the IR light source;
irradiating a second MEMS resonator configured as a reference IR irradiance sensor, and having a variation of one or more characteristic parameters of the second electrical output with the IR light from the IR light source;
computing a first ratio of one or more characteristic parameters of the first and second electrical outputs;
digitally calibrating the first ratio to a first value representative of a temperature change induced by IR light irradiance;
for a second time period when the IR source is off:
computing a second ratio of one or more characteristic parameters of the first and second electrical outputs;
digitally calibrating the second ratio to a second value representative of a temperature change not induced by IR light irradiance; and
computing a difference between the first value and the second value.

14. The NDIR sensing method of claim 13, wherein the one or more characteristic parameters of the first and second electrical outputs are one or more of amplitude, frequency, or phase of the first and second electrical outputs.

15. The NDIR sensing method of claim 13, further comprising comparing the computed difference between the first value and the second value with a threshold value, and outputting an asserted binary gas detection output indicative of positive detection of a gas based on the computed difference exceeding the threshold value, wherein the first MEMS device is configured with an absorption profile center wavelength matched to a characteristic IR absorption wavelength of the gas.

16. A nondispersive infrared (NDIR) sensor comprising:
a clock having a periodic cycle;
an infrared (IR) chopper comprising an IR light source having on and off states controlled by the clock;
a first microelectromechanical systems (MEMS) device configured as a measurement IR irradiance sensor and having a detection IR absorption response curve having a peak centered at a wavelength of interest, and the first MEMS device having a first electrical output;
a second MEMS device configured as a reference IR irradiance sensor and having a second electrical output, wherein the second MEMS device is configured either as
a broadband IR reflector comprising a substantially uniform metal reflecting surface, or
an IR absorber configured with a reference IR absorption response curve having a peak centered at the wavelength of interest and having a lower quality factor than a detection IR absorption response curve; and
a parameter-ratio engine having first and second inputs to which the first and second electrical outputs are respectively coupled, the parameter-ratio engine configured to compute a ratio of one or more characteristic parameters of the first and second electrical outputs.

17. The NDIR sensor of claim 16, wherein the second MEMS device is configured as the IR absorber and comprises a plasmonic metasurface comprising square or rectangular metapatches.

18. The NDIR sensor of claim 17, wherein the first MEMS device comprises a plasmonic metasurface comprising cross-shaped metapatches.

19. The NDIR sensor of claim 16, further comprising:
first and second registers coupled to the parameter-ratio engine and configured to respectively store a first computed ratio of measurements made of the first and second electrical output signals during a time period when the IR light source is in the on state, and a second computed ratio of measurements made of the first and second electrical output signals during a time period when the IR light source is in the off state; and
a subtractor coupled to respective outputs of the first and second registers and configured to subtract a second value based on the second computed ratio from a first value based on the first computed ratio to provide an output digital word that is proportional to an irradiance of the first MEMS device by the IR light source.

20. A gas concentration sensor or gas detector comprising the sensor of claim 16 and a sample chamber, the IR light source arranged at an opposite end of the sample chamber from the first and second MEMS devices.
